(19) United States
(12) Patent Application Publication
(10) Pub. No.: US 2011/0277631 A1
(43) Pub. Date: Nov. 17, 2011

(54) METHOD FOR MODIFYING A POLYIMIDE MEMBRANE

(75) Inventors: Lu Shao, Singapore (SG); Tai-Shung Chung, Singapore (SG); Cher-Hon Lau, Singapore (SG)

(73) Assignee: National University of Singapore, Singapore (SG)

(21) Appl. No.: 12/945,796

(22) Filed: Nov. 12, 2010

Related U.S. Application Data
(60) Provisional application No. 61/260,739, filed on Nov. 12, 2009.

(51) Int. Cl. B01D 71/64; B01D 67/00; C23C 16/448; B01D 53/22; C23C 16/44

(52) U.S. Cl. 95/51; 95/45; 427/255.6

(57) ABSTRACT

There is provided a method for modifying a polyimide membrane comprising the step of exposing the polyimide membrane to a surface modification compound in a vapour phase, said surface modification compound having at least one amine group, to thereby modify the polyimide membrane.

### CROSS-REFERENCE TO RELATED APPLICATIONS

This application claims priority to and the benefit of U.S. Provisional Patent Application Ser. No. 61/260,739, filed Nov. 12, 2009, entitled “Polyimide Membranes Modified By Vapor-phase Reagents For Separations” and is incorporated herein by reference in its entirety. It is understood that, in the event of a discrepancy between this application and the applications incorporated by reference above, the information contained in this application shall take precedence.

### TECHNICAL FIELD

The present invention generally relates to a method for modifying a polyimide membrane. The present invention also relates to a modified polyimide membrane.

### BACKGROUND

Hydrogen is one of the most promising candidates for clean energy due to the sole combustion product of water. Hydrogen is produced mainly from the steam methane reforming (SMR) method followed by the water-gas shift (WGS) reaction. However, the WGS reaction produces a mixture of CO₂ and H₂ gases thereby requiring high efficiency separation to produce H₂ in relatively high purity for down-stream methods and applications. Traditionally, energy-intensive methods like pressure swing adsorption and cryogenic distillation have been used to achieve this purpose. However, in recent times, membrane technology has been an energy efficient alternative to achieve high H₂/CO₂ separation. Furthermore, membrane technology also has the advantages of being cost effective, relatively simple to operate, more compact and more environmentally friendly.

Membranes for the separation of CO₂ and H₂ can be classified as CO₂-selective membranes or H₂-selective membranes. CO₂-selective membranes have high CO₂/H₂ selectivity and have the advantage of eliminating the re-pressurizing method after hydrogen purification. However, poly(ethylene oxide), which is the best performing CO₂-selective membrane material, demonstrates high CO₂/H₂ selectivity only at a cryogenic temperature of −4° F. (−20° C.). This cryogenic temperature is incompatible with the high temperature methods of SMR and WGS.

On the other hand, H₂-selective membranes have high H₂/CO₂ selectivity. Research attempts to modify polyimide, which is an attractive membrane material for H₂-selective membranes because of its versatility, processability and good mechanical properties, have been aimed at providing both properties of high permeability and high permselectivity to polyimide membranes. Polyimide membranes have been modified by cross-linking polyimides with various diamines in methanol solution in order to overcome low gas selectivity and performance decay due to ageing. The solution approach of modifying polyimide membranes has been disclosed in PCT/SG2005/000243. However, there are challenges associated with this approach when used to modify hollow fiber membranes. Membrane integrity especially in hollow fiber membranes is compromised because the thin outer layer of the hollow fibers tends to swell in the presence of methanol and diamines. It is therefore difficult to maintain intrinsic gas separation properties when the structural integrity of the membrane is compromised.

There is a need to provide a method of modifying a polyimide membrane that overcomes, or at least ameliorates, one or more of the disadvantages described above.

There is a need to provide mechanically strong polyimide membranes that have high H₂/CO₂ selectivity.

### SUMMARY

According to a first aspect, there is provided a method for modifying at least one property of a polyimide membrane comprising the step of exposing the polyimide membrane to a surface modification compound in a vapor phase, said surface modification compound having at least one amine group, to thereby modify the at least one property of the polyimide membrane.

Preferably, the surface modification compound may be a cross-linking compound having at least two amine groups.

The method may optionally exclude the step of immersing the polyimide membrane into a solution of the surface modification compound.

In one embodiment, there is provided a method for modifying at least one property of a polyimide membrane comprising the step of exposing the polyimide membrane to a surface modification compound in a vapor phase, said surface modification compound having at least one amine group, to thereby modify the at least one property of the polyimide membrane, wherein the method excludes the step of immersing the polyimide membrane into a solution of the surface modification compound.

In one embodiment, there is disclosed a method of increasing the selectivity of a polyimide material for at least one of the following gas mixtures He/N₂, H₂/N₂, H₂/CO₂ and O₂/N₂, the method comprising the step of exposing the polyimide membrane to a surface modification compound in a vapor phase, said surface modification compound having at least one amine group, to increase the selectivity of the polyimide membrane. This is in comparison to the selectivity of an unmodified polyimide membrane or a polyimide membrane which has been modified according to the prior art solution approach. In one embodiment, when the surface modification compound is a cross-linking compound having at least two amine groups, the selectivity is increased by at least 30, at least 40, at least 50, at least 60, at least 70, at least 80, at least 90 or at least 100. The modified polyimide membrane may exhibit a H₂/CO₂ selectivity of at least 30, at least 40, at least 50, at least 60, at least 70, at least 80, at least 90 or at least 100.

As the vapor phase of the surface modification compound is used instead of the solution form, the modified polyimide (or copolyimide) membrane does not suffer from swelling effects, which would occur when a solution is used. Hence, the disclosed method can be used to make hollow fibers while maintaining the structural strength and integrity of the hollow fibers because the disclosed method merely alters the microstructure of the polyimide (or copolyimide) layer. However, the prior art method of using a surface modification compound in the solution form swells the hollow fiber such that the hollow fiber is damaged and cannot be used. Accordingly, the disclosed method can be used to modify the polyimide (or copolyimide) layer in hollow fibers, which would not be possible when using the prior art method due to the swelling effects.

Further, by using the vapor phase of the surface modification compound when modifying the outer polyimide (or copolyimide) layer in a hollow fiber, only the surface layer that is exposed to the vapor is modified, while the inner core of the hollow fibre is not modified. Hence, the disclosed method provides a way to selectively modify the outer layer of the hollow fiber and thereby selecting the layer in which the property (such as gas permeability or gas selectivity) is to be modified. In addition, the thickness of the modified layer can be controlled by controlling the exposing time, which increases the flexibility of the modification method. This is in comparison to the prior art method which does not allow for the selective modification of the outer layer of the hollow fiber and cannot be controlled since the entire hollow fiber would be placed into the solution. By placing the hollow fiber into the solution, the solution permeates the entire hollow fiber and would modify the entire hollow fiber since it is not possible to block certain regions from the solution. This leads to a reduction in the overall gas permeabilities. This is not ideal for large scale applications where high gas permeabilities and high gas selectivity are preferred. In addition, it would not be possible to control the thickness of the modified layer using the prior art method.

Still further, the surface modification compound in the vapor phase can be reused, resulting in cost savings. This is not possible when the polyimides are exposed to a solution of cross-linking compounds because small traces of remnant solvents that remain in the hollow fiber as the hollow fibers are immersed in the methanol-diamine solution might contaminate the methanol-diamine solution. Additionally, the action of fiber removal from the solution removes some methanol-diamine solution, thus reducing the overall diamine concentration in the remaining solution.

Even further, the disclosed method results in a substantial improvement in the selectivity of the modified polyimide (or copolyimide) membrane or hollow fiber to a mixture of gases as compared to that made using the prior art solution immersion method. The H₂/CO₂ selectivity may be increased by a factor of at least 7 when the polyimide membrane is exposed to a vapor phase of the cross-linking compound having at least two amine groups as compared to immersing the polyimide membrane directly into a solution of the cross-linking compound.

Even further, in the solution approach, the concentration of the surface modification compound in the solution is low (about 2 wt %) and hence, the loss in the gas permeabilities of the polyimide membrane cannot be adequately controlled. However, in the vapour approach, since the vapour is made up of a higher percentage of surface modification compound (or 100% of the vapour is the surface modification compound), a greater control over the loss in the gas permeabilities of the polyimide modification can be obtained.

The conditions during the exposing step may result in a modified polyimide membrane with a different permeability as compared to an unmodified polyimide membrane or a polyimide membrane that had been modified using the direct solution immersion method.

According to a second aspect, there is provided a method of modifying a hollow fiber comprising a polyimide membrane, the method comprising the step of exposing the polyimide membrane to a surface modification compound in a vapor phase, said surface modification compound having at least one amine group, to thereby modify the hollow fiber.

According to a third aspect, there is provided a method of modifying at least one property of a hollow fiber comprising a polyimide membrane, the method comprising the step of exposing the polyimide membrane to a surface modification compound in a vapor phase, said surface modification compound having at least one amine group, to thereby modify the at least one property of the hollow fiber.

In one embodiment, there is provided a method of modifying at least one property of a hollow fiber comprising a polyimide membrane, the method comprising the step of exposing the polyimide membrane to a surface modification compound in a vapor phase, said surface modification compound having at least one amine group, to thereby modify the at least one property of the hollow fiber, wherein the method excludes the step of immersing the hollow fiber into a solution of the surface modification compound.

According to a fourth aspect, there is provided a polyimide membrane exhibiting a H₂/CO₂ selectivity of at least 30, at least 40, at least 50, at least 60, at least 70, at least 80, at least 90 or at least 100.

In one embodiment, there is provided a modified polyimide membrane made in a method comprising the step of exposing the polyimide membrane to a surface modification compound in a vapor phase, said surface modification compound having at least one amine group, to thereby modify the polyimide membrane, wherein the method excludes the step of immersing the hollow fiber into a solution of the surface modification compound.

In one embodiment, there is provided use of the membrane as defined above in a hollow fiber, a separation system, a gas separation module, or a pervaporation module.

According to a fifth aspect, there is provided a method for separating at least one fluid or particle from a mixture comprising the steps of:

(a) contacting the mixture with one side of the membrane as defined above; and

(b) applying a pressure to the one side of the membrane to cause the at least one fluid or particle to permeate said membrane.

According to a sixth aspect, there is provided a method for separating carbon dioxide from a gas mixture comprising carbon dioxide and at least one of methane and hydrogen, the method comprising the steps of:

(a) contacting the gas mixture with one side of the membrane as defined above; and

(b) applying a pressure to the gas mixture in contact with said treated polyimide membrane to cause at least a portion of said carbon dioxide present in said gas mixture to permeate said treated polyimide membrane.

### DEFINITIONS

The following words and terms used herein shall have the meaning indicated:

The term “inherent viscosity” as used herein refers to ratio of the natural logarithm of the relative viscosity to the concentration of the polymer in grams per 100 ml of solvent.

The phrase “modifying at least one property”, as used herein, refers to modifying at least one performance characteristic of the polyimide membrane. The performance characteristic of the polyimide membrane may include the selectivity of the polyimide membrane to a mixture of gases, such as H₂/CO₂ selectivity or the permeability of the polyimide membrane to a mixture of gases, such as H₂ and CO₂ permeability.

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Certain embodiments may also be described broadly and generically herein. Each of the narrower species and subgeneric groupings falling within the generic disclosure also form part of the disclosure. This includes the generic description of the embodiments with a proviso or negative limitation removing any subject matter from the genus, regardless of whether or not the excised material is specifically recited herein.

### DETAILED DISCLOSURE OF EMBODIMENTS

Exemplary, non-limiting embodiments of a method for modifying at least one property of a polyimide membrane will now be disclosed. The method for modifying at least one property of a polyimide membrane comprises the step of exposing the polyimide membrane to a surface modification compound in a vapor phase, said surface modification compound having at least one amine group, to thereby modify the polyimide membrane.

The surface modification compound may have cross-linking functionality where there are two or more amine groups on the surface modification compound and hence such compounds can be considered “cross-linking compounds”.

The method may comprise the step of, during the exposing step, maintaining the conditions to form an amide bond between imide groups of the polyimide and amine groups of the surface modification compound.

The disclosed method may result in a substantial improvement in the selectivity of the modified polyimide (or copolyimide) membrane or hollow fiber to a mixture of gases as compared to that made using the prior art solution immersion method. The H₂/CO₂ selectivity may be increased by a factor of at least 7 when the polyimide membrane is exposed to a vapor phase of the cross-linking compound having at least two amine groups as compared to immersing the polyimide membrane directly into a solution of the cross-linking compound.

The disclosed method may increase the selectivity of a polyimide membrane for at least one of the following gas mixtures He/N₂, H₂/N₂, H₂/CO₂ and O₂/N₂, the method comprising the step of exposing the polyimide membrane to a surface modification compound in a vapor phase, said surface modification compound having one amine group, to increase the selectivity of the polyimide membrane. In one embodiment, when the surface modification compound is a cross-linking compound having at least two amine groups, the selectivity is increased by at least 30, at least 40, at least 50, at least 60, at least 70, at least 80, at least 90 or at least 100.

The modified polyimide membrane may exhibit a H₂/CO₂ selectivity of at least 30, at least 40, at least 50, at least 60, at least 70, at least 80, at least 90 or at least 100.

### Surface Modification Compound

The surface modification compound may have one or more amine groups, i.e., 1, 2, 3, 4, 5, 6, 7, 8, 9, 10 or more amine groups.

Preferably, the surface modification compound may be a cross-linking compound having two or more amine groups, i.e., 2, 3, 4, 5, 6, 7, 8, 9, 10 or more amine groups.

The surface modification compound may have the following general formula (I):

(H₂N)ₙ—R (I)

wherein:

R is a hydrocarbon; and n is an integer greater than 0. In one embodiment, n is 1 and such exemplary surface modification compounds include methylamine, ethylamine, propylamine, butylamine, ethyleneamine, propyleneamine and butyleneamine. In another embodiment, n is greater than 1.

In embodiments where the surface modification compound has more than one amine group, the surface modification compound exhibits cross-linking functionality and hence is a cross-linking compound whereby the amine groups present in the cross-linking compound serve to cross-link a plurality of polyimide polymers together to form a cross-linked structure.

Accordingly, the surface modification compound may be a diamine cross-linking compound. The diamine cross-linking compound is represented by the following formula (Ia) in which the two amine groups are chemically coupled by the hydrocarbon linker (R):

H₂N—R—NH₂ (Ia)

The hydrocarbon linker R may be a saturated or unsaturated, branched or straight chain aliphatic or an aliphatic ring hydrocarbon.

The saturated or unsaturated branched or straight chain aliphatic hydrocarbon linker R may have a number of carbon atoms selected from the group consisting of: 1 to about 18, 1 to about 12, 1 to about 8, 1 to about 6, 1 to about 4, about 2 to about 18, about 6 to about 18, about 8 to about 18 and about 12 to about 18, 3 to about 18, 3 to about 12, 3 to about 8, 3 to about 6, 3 to about 4 and about 4 to about 18.

Exemplary aliphatic hydrocarbons include alkyls such as methyl, ethyl, propyl, isopropyl, butyl and tertbutyl, pentyl, hexyl, heptyl, octyl; alkenyls such as ethenyl, propenyl, isopropenyl, and butenyl; alkynyls such as ethynyl, propynyl, isopropynyl, and butynyl; cycloalkyls such as cyclopropyl, cyclobutyl, cyclopentyl, and cyclohexyl; cycloalkenyls such as cyclopentenyl, cyclohexenyl and cycloheptenyl; heterocycloalkyls such as oxiranyl, and tetrahydropyranyl; and heterocycloalkenyls.

Exemplary diamine cross-linking compounds may be selected from the group consisting of ethylenediamine (EDA), propylenediamine, trimethylenediamine, diethylenetriamine, triethylenetertramine, hexamethylenediamine, heptamethylenediamine, octamethylenediamine, nonamethylenediamine, decamethylenediamine, 1,12-dodecanediamine, 1,18-octadecanediamine, 3-methylheptamethylenediamine, 4,4-dimethylheptamethylenediamine, 4-methylnonamethylenediamine, 5-methylnonamethylenediamine, 2,5-dimethylhexamethylenediamine, 2,5-dimethylheptamethylenediamine, 2,2-dimethylpropylenediamine, N-methyl-bis(3-aminopropyl) amine, 3-methoxyhexamethylenediamine, 1,2-bis(3-aminopropoxy)ethane, bis(3-aminopropyl)sulfide, 1,4-cyclohexanediamine, bis-(4-aminocyclohexyl)methane, m-phenylenediamine, p-phenylenediamine, 2,4-diaminotoluene, 2,6-diaminotoluene, m-xylylenediamine, p-xylylenediamine, 2-methyl-4,6-diethyl-1,3-phenylene-diamine, 5-methyl-4,6-diethyl-1,3-phenylene-diamine, benzidine, 3,3′-dimethylbenzidine, 3,3′-dimethoxybenzidine, 1,5-diaminonaphthalene, N,N′-dimethylethylene diamine, N,N′-diethylethylenediamine, 1,3-diamino-4-isopropylbenzene, and mixtures thereof.

Exemplary aliphatic amines may be selected from the group consisting of methylamine, ethylamine, propylamine, isopropylamine, butylamine, isobutylamine, cyclohexylamine, cyclohexanebis(methylamine), dimethylamine, diethylamine, dipropylamine, diisopropylamine, 3-aminopropyldimethylethoxysilane, 3-aminopropyldiethoxysilane, N-methylaminopropyltrimethoxysilane, 3-aminopropyltriethoxysilane, N-methylaminopropyltrimethoxysilane, bis(4-aminophenyl)methane, bis(2-chloro-4-amino-3,5-diethylphenyl)methane, bis(4-aminophenyl)propane, 2,4-bis(b-amino-t-butyl) toluene, bis(p-b-amino-t-butylphenyl)ether, bis(p-b-methyl-o-aminophenyl)benzene, bis(p-b-methyl-o-aminopentyl)benzene, bis(4-aminophenyl)sulfide, bis(4-aminophenyl)sulfone, bis(4-aminophenyl)ether and 1,3-bis(3-aminopropyl)tetramethyldisiloxane or 3-aminopropyl terminated polydimethylsiloxanes.

Compounds that contain more than 2 amine groups may be selected from the group consisting of diethylenetriamine, triethylenetetraamine, tetraethylene pentaamine and pentaethylenehexamine.

Exemplary aromatic diamines may include meta-xylylenediamine, para-xylylenediamine and the like.

It is to be noted that any type of diamines can be used as long these diamines are able to vaporize and modify the polyimide membrane.

### Polyimide or Copolyimide Polymer

The polyimide or copolyimide polymer may have the structural formula II:

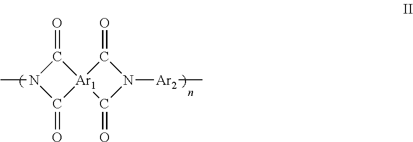

wherein
Ar₁ is a quadrivalent organic group,
Ar₂ is a divalent organic group, and
n is the number of monomer units in the polyimide where n is a number from about 10 to about 500 such that the polyimide has an inherent viscosity of at least 0.3 as measured at 77° F. (25° C.) on a 0.5% by weight solution in N-methylpyrrolidinone. The inherent viscosity may be in the range of about 0.3 to about 1.

The quadrivalent organic group Ar₁ may be selected from the group consisting of:

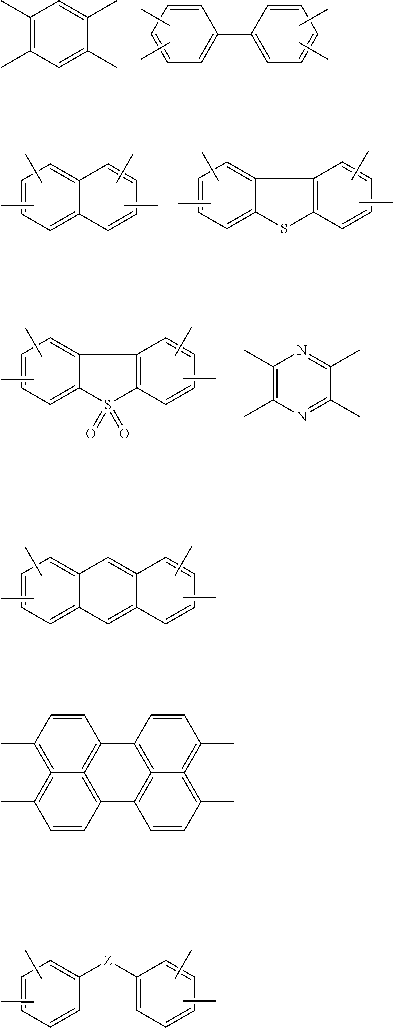

The divalent organic group Ar₂ may be selected from the group consisting of:

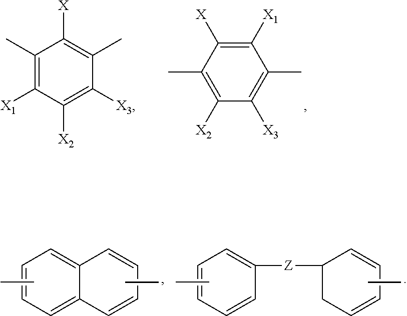

Z may be selected from the group consisting of:

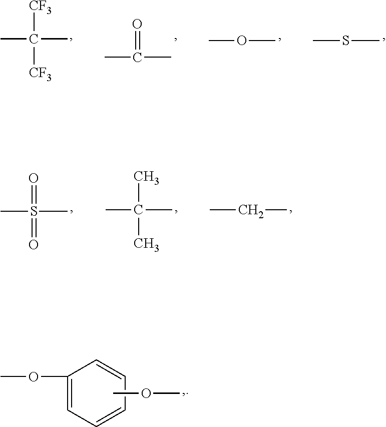

X, X₁, X₂ and X₃ are each independently selected from hydrogen, C₁ to C₅ alkyl groups, C₁ to C₅ alkoxy groups, phenyl or phenoxy groups.

The polyimide may also be a polyimide having a similar structure as that of ULTEM® (polyetherimide), MATRIMID®, P84® (BTDA-TDI/MDI, copolyimide of 3,3′4,4′-benzophenone tetracarboxylic dianhydride and 80% methylphenylene-diamine+20% methylene diamine) or similar materials and blends.

The polyimide may be an aromatic polyimide. The polyimide may comprise one or more ketone groups.

In one embodiment, the polyimide may be in the form of a polyimide film. Polyimide powders are first dissolved in a suitable halogenated solvent such as dichloromethane to form a polymer solution. The concentration of the polymer solution may be selected from the range of about 1% (w/w) to about 5% (w/w). The concentration of the polymer solution may be about 2% (w/w). The polymer solution is then filtered to remove excess polyimide powers and then cast onto a silicon wafer plate. The casting temperature used may be selected from the range of 73.4° F. (23° C.) to 86° F. (30° C.). The casting temperature used may be room temperature (or 73.4° F. (23° C.)). After controlled evaporation, the nascent polyimide films were dried in a vacuum to remove the residual solvent. The drying temperature may be selected from the range of about 437° F. (225° C.) to about 527° F. (275° C.). The drying temperature may be about 482° F. (250° C.). The drying time may be selected from the range of about 36 hours to about 60 hours. The drying time may be about 48 hours. The thickness of the resultant polyimide film may be selected from the range of about 50 nm to about 500 μm.

### Modification Process

As the polyimide or copolyimide is exposed to the vapour-phase surface modification compound, the surface modification compound reacts with the polyimide or copolyimide by breaking one of the C—N bonds in the imide group to form an amide group with the carboxyl moiety. This is due to the strong nucleophilicity of the surface modification compound. In embodiments where the polyimide or copolyimide has two imide groups and the surface modification compound has more than one amine groups, one or both of the imide groups may be converted into amide groups by the cross-linking compound. The resultant structure is one in which two or more polyimides or copolyimides are cross-linked to each other via amide bonds with the cross-linking compound. An exemplary cross-linked structure can be seen below.

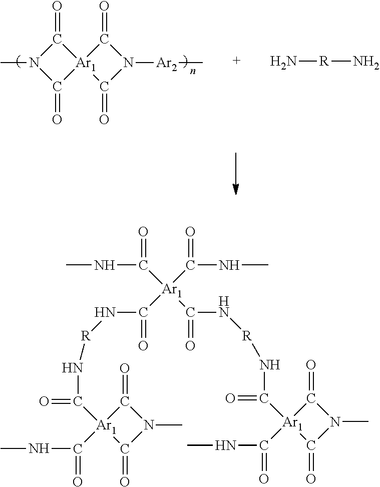

The polyimide may be exposed to the surface modification compound in the vapour phase at a temperature selected from the range consisting of about 50° F. (10° C.) to about 212° F. (100° C.), about 68° F. (20° C.) to about 212° F. (100° C.), about 86° F. (30° C.) to about 212° F. (100° C.), about 104° F. (40° C.) to about 212° F. (100° C.), about 122° F. (50° C.) to about 212° F. (100° C.), about 140° F. (60° C.) to about 212° F. (100° C.), about 158° F. (70° C.) to about 212° F. (100° C.), about 176° F. (80° C.) to about 212° F. (100° C.), about 194° F. (90° C.) to about 212° F. (100° C.), about 50° F. (10° C.) to about 194° F. (90° C.), about 50° F. (10° C.) to about 176° F. (80° C.), about 50° F. (10° C.) to about 158° F. (70° C.), about 50° F. (10° C.) to about 140° F. (60° C.), about 50° F. (10° C.) to about 122° F. (50° C.), about 50° F. (10° C.) to about 104° F. (40° C.), about 50° F. (10° C.) to about 86° F. (30° C.), about 50° F. (10° C.) to about 68° F. (20° C.), about 68° F. (20° C.) to about 86° F. (30° C.), and about 75.2° F. (24° C.) to about 78.8° F. (26° C.). In one embodiment, the temperature during this step may be about 77° F. (25° C.).

Where the polyimide (or copolyimide) membrane is in the form of a film, the polyimide (or copolyimide) film may be exposed to the surface modification compound for a time period selected from the range of about 1 minute to about 60 minutes, about 2 minutes to about 60 minutes, about 5 minutes to about 60 minutes, about 10 minutes to about 60 minutes, about 20 minutes to about 60 minutes, about 30 minutes to about 60 minutes, about 40 minutes to about 60 minutes, about 50 minutes to about 60 minutes, about 1 minute to about 2 minutes, about 1 minute to about 5 minutes, about 1 minute to about 10 minutes, about 1 minute to about 20 minutes, about 1 minute to about 30 minutes, about 1 minute to about 40 minutes and about 1 minute to about 50 minutes. The exposing time may be separately about 2 minutes, about 5 minutes or about 10 minutes.

It is to be appreciated that the selection of the exposure time is dependent on the thickness of the polyimide membrane and the exposing temperature. If the polyimide membrane is thicker, a longer time will be needed to modify the polyimide to the required specifications. If the exposing temperature is higher such that more vapour can be produced from the solution, then the exposing time can be shortened.

When the polyimide (or copolyimide) membrane is in the form of a hollow fiber, the exposing time should be chosen to prevent pealing of the modified polyimide (or copolyimide) layer from the surface of the hollow fiber. The exposing time is then selected from the range of about 1 minute to about 5 minutes, about 2 minutes to about 5 minutes, about 3 minutes to about 5 minutes, about 4 minutes to about 5 minutes, about 1 minute to about 2 minutes, about 1 minute to about 3 minutes and about 1 minute to about 4 minutes.

Typically, the polyimide (or copolyimide) membrane that is modified when the hollow fiber is exposed to the surface modification compound in the vapour phase is present in the outer layer of the hollow fiber. The thickness of the modified polyimide (or copolyimide) layer depends on the exposing time and may be selected from the range of about 3 μm to about 6 μm, about 3 μm to about 4 μm, about 3 μm to about 5 μm, about 4 μm to about 6 μm and about 5 μm to about 6 μm.

As compared to the prior art solution method, the disclosed method which uses the surface modification compound in the vapour phase may not substantially increase the pore size of the hollow fiber during the exposing step. The pore size of the hollow fiber may not substantially change during the exposing step. If the prior art solution method were used to modify a hollow fiber, the hollow fiber would swell upon contact with the solution, leading to an increase in the free volume of the fiber such that more surface modification compounds can diffuse across the enlarged pores and result in intense structure modification of the polyimide membrane. When this happens, the gas permeance of the hollow fiber for different gases will decrease by a smaller extent as compared to the vapour approach such that in one embodiment, the ratio between the magnitude of H₂ and CO₂ permeability reduction in the solution approach is smaller than that in the vapour approach. Solution swelling effects may also affect the structural integrity of the hollow fiber and damage the hollow fiber.

As the exposing time increases in the disclosed method, the channels for gas transport in the modified polyimide membrane become smaller such that the gas permeability of these modified hollow fibers decreases. In one embodiment, the ratio between the magnitude of H₂ and CO₂ permeability reduction in the vapour approach is greater than that in the solution approach. Hence, H₂/CO₂ selectivity increases with increasing exposing time. The modified polyimide membrane may exhibit a H₂/CO₂ selectivity of at least 30, at least 40, at least 50, at least 60, at least 70, at least 80, at least 90 or at least 100. In one embodiment, there is provided a polyimide membrane exhibiting a H₂/CO₂ selectivity of at least 30.

In one embodiment, when the surface modification compound is a cross-linking compound having at least two amine groups, the selectivity is increased by at least 30, at least 40, at least 50, at least 60, at least 70, at least 80, at least 90, or at least 100, when compared to an unmodified polyimide membrane or a polyimide membrane which has been modified according to the prior art solution approach.

The polyimide membrane may be exposed to a solution of the surface modification compound (but not directly immersed in the solution). The solution may undergo a vaporizing step to generate the vapour phase. In order to increase the amount of vapour that is exposed to the polyimide (or copolyimide) membrane in an enclosed chamber, the solution may be agitated during the vaporization step. The solution may be agitated by passing a gas through the solution of the surface modification compound, the gas being inert to the surface modification compound. The presence of the inert gas serves to substantially promote the evaporation of the surface modification solution such that a greater amount of surface modification compound is present in the enclosed chamber as compared to a scenario where the inert gas is absent. The inert gas may be selected from the group consisting of a noble gas (such as helium, neon or argon), nitrogen gas, a normally gaseous hydrocarbon (such as methane, ethane, propane, or ethylene), oxygen and air.

The surface modification compound may comprise an aliphatic hydrocarbon chemically coupled to the amine group. In one embodiment, the aliphatic hydrocarbon is an alkyl group. The alkyl group may be a lower alkyl group having 1 to 8 carbon atoms, or 1 to 6 carbon atoms, or 1 to 3 carbon atoms.

After the exposing step, excess surface modification compound is removed from the modified polyimide film or hollow fiber. The excess surface modification compound can be removed by either washing the modified polyimide film or subjecting the modified hollow fiber to a vacuum at a temperature and time sufficient to remove the excess surface modification compound. The temperature used may be room temperature (that is about 73.4° F. (23° C.)) and the time used may be about 2 hours.

### Polyimide Membrane

The polyimide may be modified by the surface modification compound before or after membrane fabrication. Hence, there is disclosed a modified polyimide membrane made in a method which comprises the step of exposing the polyimide membrane to a surface modification compound in a vapor phase, surface modification compound having at least one amine group, to thereby modify the polyimide membrane.

The modified polyimide membrane may exhibit a H₂/CO₂ selectivity of at least 30, at least 40, at least 50, at least 60, at least 70, at least 80, at least 90 or at least 100.

The membrane may have an improved selectivity to a mixture of gases as compared to a membrane made using the prior art solution immersion method. The H₂/CO₂ selectivity may be increased by a factor of at least 7 when the polyimide membrane is exposed to a vapor phase of the cross-linking compound (having at least two amine groups) as compared to immersing the polyimide material directly into a solution of the cross-linking compound. The H₂/CO₂ selectivity of the disclosed membrane may be increased by a factor of at least 8, at least 9 or at least 10.

The membrane comprising the modified polyimide may be formed from film casting, extrusion or melt blowing. The polyimide membrane may be in the form of a flat sheet, a dense film, asymmetric film, asymmetric hollow fiber, dual layer hollow fiber, composite membrane of polyimides, composite (organic-inorganic) consisting of nanoparticles, or any form suitable for use in fluid separation systems or fluid/particle separation systems. Exemplary separation systems include filtration, gas separation, water treatment, pervaporation, micro-filtration, ultrafiltration, nano-filtration, and reverse osmosis.

When the membrane is formed into a hollow fiber, the polyimide membrane present in the hollow fiber may be modified by the surface modification compound in the vapour phase. Hence, there is disclosed a method of modifying a hollow fiber comprising a polyimide membrane, the method comprising the step of exposing the polyimide membrane to a surface modification compound in a vapour phase, said surface modification compound having at least one amine group, to thereby modify the hollow fiber.

The polyimide membrane may, for example, be suitable for separation of fluid mixtures such as a mixture of CO₂ and CH₄ gases, a mixture of H₂ and N₂ gases, a mixture of H₂ and CO₂ gases, a mixture of He and N₂ gases or a mixture of C₂-C₄ hydrocarbons. The polyimide membrane may be used for hydrogen purification in “syngas” production. The polyimide membrane may be used to separate oxygen from air. The polyimide membrane may also be suitable for separating particles from fluids.

There is also disclosed the use of the membrane in a hollow fiber, a separation system, a gas separation module, or a pervaporation module.

There is also provided a method for separating at least one fluid or particle from a mixture comprising the steps of (a) contacting the mixture with one side of the membrane; and (b) applying a pressure to the one side of the membrane to cause the at least one fluid or particle to permeate said membrane.

There is also provided a method for separating carbon dioxide from a gas mixture comprising carbon dioxide and at least one of methane and hydrogen, the method comprising the steps of (a) contacting the gas mixture with one side of the membrane; and (b) applying a pressure to the gas mixture in contact with said treated polyimide membrane to cause at least a portion of said carbon dioxide present in said gas mixture to permeate said treated polyimide membrane. The gas mixture may be natural gas.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1a is a schematic diagram of the experimental set-up of ethylenediamine (EDA) vapor modification method in a closed system.

FIG. 1b is a schematic diagram of the experimental set-up of EDA vapor modification method in a partially open system.

FIG. 2a is an attenuated total reflection Fourier transform infrared (FTIR-ATR) graph of the polyimide-I membrane of Example 1.

FIG. 2b is an X-ray diffraction graph of the polyimide-I membrane of Example 1.

FIG. 2c is a graph of gas permeability and H₂/CO₂ selectivity against EDA vapor exposure time of the polyimide-I membrane of Example 1.

FIG. 2d is a graph of H₂/CO₂ selectivity against H₂ permeability of the polyimide-I membrane of Example 1.

FIG. 3a is a FTIR-ATR graph of the PBI-Matrimid membrane of Example 2.

FIG. 3b is a FTIR-ATR graph of the Torlon membrane of Example 2.

FIG. 3c is a graph of various gas permeabilities of an EDA vapor modified polyimide membrane of Example 2.

FIG. 3d is a graph of various gas pair selectivities of an EDA vapor modified polyimide membrane of Example 2.

FIG. 4a is the FTIR-ATR graph of the polyimide-I hollow fiber membrane of Example 3.

FIGS. 4b(i), (ii) and (iii) show three Field Emission Scanning Electron Microscopy (FESEM) images of the polyimide-I hollow fiber membrane of Example 3 as it is exposed to the cross-linking compound for 0 minutes, 2 minutes and 5 minutes respectively.

FIGS. 4c(i), (ii) and (iii) show three FESEM images of the PBI-Matrimid hollow fiber membrane of Example 3 as it is exposed to the cross-linking compound for 0 minutes, 2 minutes and 5 minutes respectively.

FIGS. 4d(i), (ii) and (iii) show three FESEM images of the Torlon hollow fiber membrane of Example 3 as it is exposed to the cross-linking compound for 0 seconds, 30 seconds and 60 seconds respectively.

FIG. 4e is an X-ray diffraction graph of the polyimide-I hollow fiber membrane of Example 3.

FIG. 4f is a graph of H₂ permeability and H₂/CO₂ selectivity against EDA vapor exposure time of the polyimide-I hollow fiber membrane of Example 3.

### EXAMPLES

Non-limiting examples of the invention and a comparative example will be further described in greater detail by reference to specific Examples, which should not be construed as in any way limiting the scope of the invention.

Membrane Fabrication

To produce the polyimide membrane films used in the Examples described below, polyimide powders are dried overnight at 120° C. under a vacuum pressure of between 3-10 torr. A 2% (w/w) of polymer solution was prepared by dissolving the dried polyimide powders in dichloromethane. The polymer solution was then filtered with 1 μm filters (Whatman, Kent, United Kingdom) and cast onto a silicon wafer plate at room temperature (about 73.4° F. (23° C.)). After controlled evaporation, the nascent films were dried in a vacuum pressure of between 3-10 torr at 482° F. (250° C.) for 48 hrs to remove the residual dichloromethane solvent.

The hollow fibers used in Example 3 were spun using the conditions found in Table 1.

| | | PBI- | Torlon |
|---|---|---|---|
| | Polyimide-I/PES | Matrimid/PSf | single |
| Sample Name | dual layer | dual layer | layer |
| Outer- | 27 wt % 6FDA-NDA, | 22 wt % PBI- | 28 wt % |
| layer dope | 73 wt % NMP/THF: | Matrimid ® | Torlon ®, |
| composition | 5:3 (w/w) | (1:1), 78 | 72 wt % NMP |
| | | wt % DMAc | |
| Inner- | 30 wt % PES, | 75 wt % PSf, | — |
| layer dope | 70 wt % NMP/H₂O: | 25 wt % in | |
| composition | 10:1 (w/w) | NMP | |
| Bore fluid | 95/5 NMP/H₂O | 95/5 NMP/H₂O | 90/10 |
| Composition | | | NMP/H₂O |
| External | Water | Water | Water |
| coagulant | | | |
| Outer | 0.2 | 0.3 | 2 |
| layer dope | | | |
| flow rate | | | |
| (ml/min) | | | |
| Inner | 0.8 | 2 | — |
| layer dope | | | |
| flow rate | | | |
| (ml/min) | | | |
| Bore fluid flow | 0.3 | 1 | 1 |
| rate (ml/min) | | | |
| Coagulation | 25 | 25 | 25 |
| bath temper- | | | |
| ature (° C.) | | | |
| Spinneret | 50 | 25 | 50 |
| temper- | | | |
| ature (° C.) | | | |
| Take-up rate | Free Fall | Free Fall | 20 |
| (cm/min) | | | |
| Air gap (cm) | 8 | 1 | 5 |

The polyimide powders used are as follows: 6FDA (4,4′-(hexafluoroisopropylidene)diphthalic anhydride) is supplied by Clariant, Germany; NDA (1,5-napthalenediamine) is supplied by Acros Organics, New Jersey, United State of America; Polybenzimidazole (PBI) is supplied by Aldrich Chemical Company Inc., Milwaukee, United States of America; Matrimid® 5218 is supplied by Vantico, Luxembourg; Torlon® 4000T-MV poly(amide imide), Udel® 3500 polysulfone (PSf), and Radel A-300P polyethersulfone (PES) are supplied by Amoco Polymers Inc, Marietta, Ohio, United States of America.

The polyimide films obtained were chosen with thickness of about 0.5 μm to about 500 μm for further vapor-phase diamine modification.

Vapor-Phase Diamine Modification of Membranes

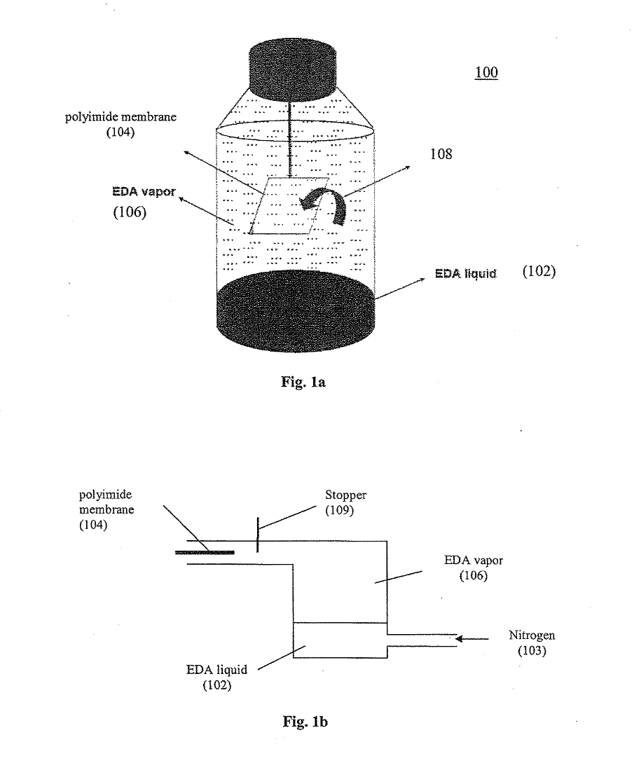

FIG. 1a describes an exemplary experimental set-up of an EDA vapor modification method in a closed system. The closed vapor modification system 100 contains a predetermined amount of EDA liquid 102 (obtained from Sigma-Aldrich, Missouri of the United States of America). After liquid-vapor equilibrium is established at a temperature of 77±1° F. (25±1° C.), a polyimide membrane 104 was suspended and exposed to the EDA vapor 106 for a period of time. Arrow 108 shows the EDA vapor 106 permeating and reacting with the membrane 104. After some time, the membrane 104 was removed and washed with pure water to remove any unreacted residual EDA present. The membrane 104 was annealed at 158° F. (70° C.) for about 1 day to ensure complete removal of any unreacted diamines.

An alternative experimental set-up of an EDA vapor modification method in a partially open system is described in FIG. 1b. This set-up was used to modify the polyimide membranes in the subsequent examples. In this set-up, inert nitrogen gas 103 was bubbled into the EDA liquid 102 to enhance EDA evaporation from the liquid 102. After liquid-vapor equilibrium was established at 77±1° F. (25±1° C.), a polyimide membrane 104 was exposed to the EDA vapor 106 for a period of time by opening the stopper 109. After exposure, the membrane 104 was dried under vacuum at room temperature for 2 hours to remove any unreacted residual EDA.

Based on Antoine equation calculations, the vapor pressure of EDA vapor is 11.99 mmHg and the amount of EDA vapor in air is 1.577% v/v.

After exposure to the EDA vapor, the polyimide membranes were analyzed using attenuated total reflection Fourier transform infrared (FTIR-ATR) to determine the effectiveness of EDA vapor modification on the membrane surfaces.

The physical properties of the polyimide membranes were also analyzed by X-ray Diffraction to determine the effectiveness of the polyimide membranes in H₂/CO₂ separation. The most important factor used to interpret the change in physical properties is the space between polymer chains, or the “d-space”, as used herein.

In the following Examples, different modified polyimide membranes are analyzed and the results are discussed below.

### Example 1

In this Example, 6FDA-NDA flat sheet polyimide membranes (hereafter known as “polyimide-I membrane”) was used. The 6FDA-NDA polyimide has the following structure.

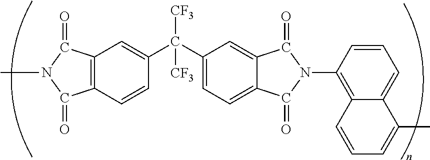

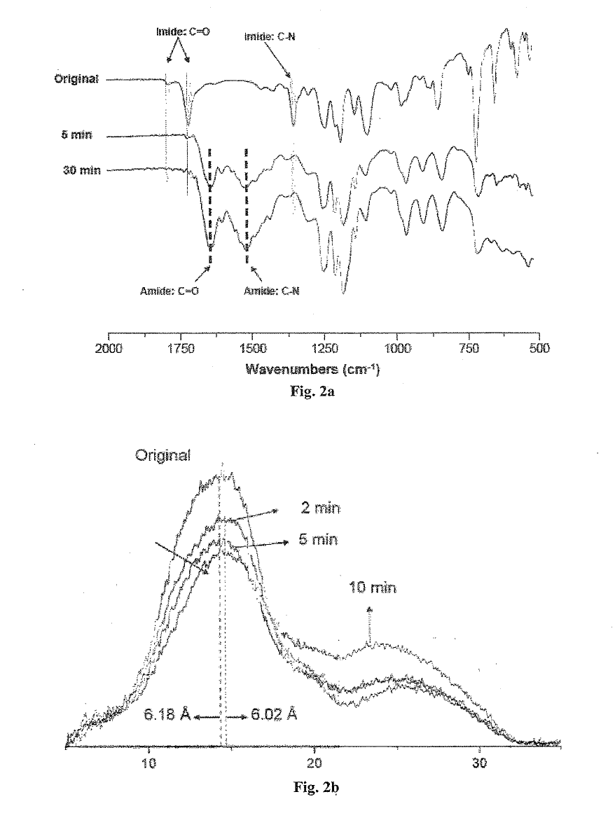

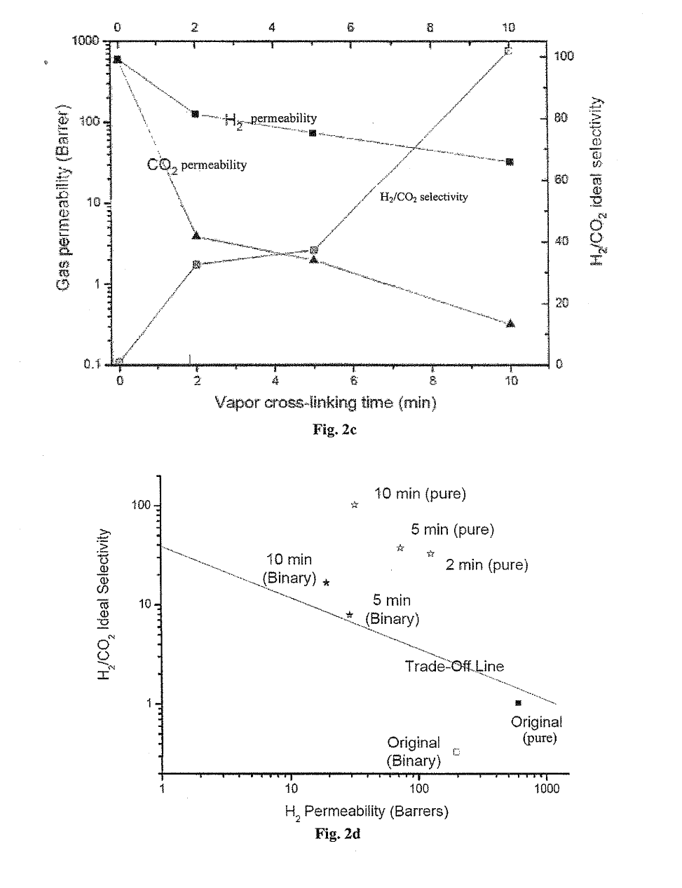

After 5 minutes of exposure to EDA vapor, the polyimide-I membrane was analyzed by FTIR-ATR. FIG. 2a shows the FTIR-ATR graph of the polyimide-I membrane before and after exposure to EDA vapor. As can be seen in FIG. 2a, the bands at around the asymmetric stretch of the C═O portion of imide groups (1785 cm⁻¹), the symmetric stretch of the C═O portion of imide groups (1718 cm⁻¹) and the stretch of the C—N portion of imide groups (1352 cm⁻¹) came from the original polyimide-I membrane. After EDA vapor modification, the imide peaks disappear and a new band of the C═O portion of amide (CONH) groups and the N—H portion and C—N portion of the CONH groups appeared at around 1644 cm⁻¹ and 1520 cm⁻¹ respectively.

The reaction mechanism of vapour-phase EDA modification of polyimide-I membrane is shown below.

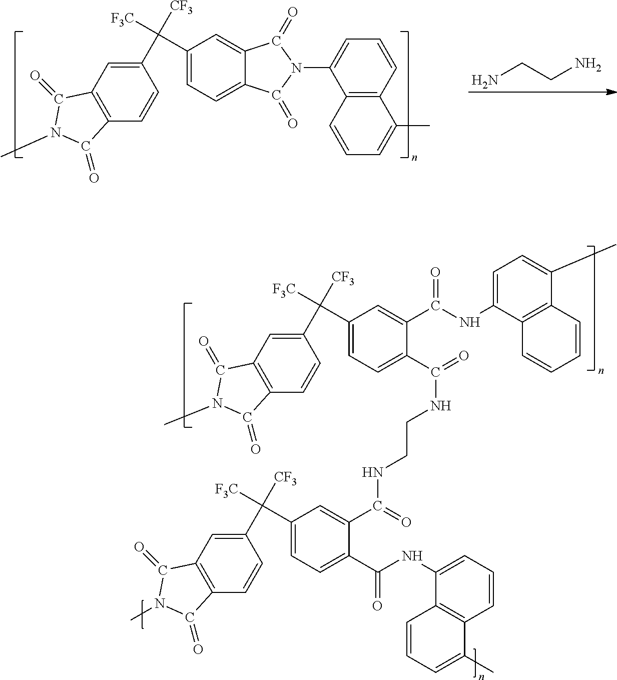

### Reaction Mechanism

As shown above, the imide groups in the polyimide were converted into amide groups with a simultaneous cross-linking between the polymer chains due to the strong nucleophilicity of EDA.

Further, X-ray photoelectron spectroscopy (XPS) was used to confirm the FTIR-ATR results. Since the fluorine content in the membranes was kept constant after EDA modification, the ratio of nitrogen to fluorine (N/F) can be used to quantify the reactions because the nitrogen from EDA increases the nitrogen content in the membranes. The N/F ratio of the polyimide-I membrane increased significantly from 0.31 to 0.83, showing that the EDA had reacted and formed cross-links with the polyimide-I membrane.

The XRD result of the polyimide-I membrane before and after exposure to EDA vapor is shown in FIG. 2b. After exposure to EDA vapor, the d-space shifted from about 6.18 Å to about 6.02 Å. The d-space change of the polyimide-I membrane after EDA vapor modification indicated an alteration of the packing conformation of polymer chains because of the cross-links formed. Specifically, the polymer chain packing had become tighter. There was also a shift in the intensity of the main peak in the polyimide-I membrane after EDA vapor modification. These findings indicate a tighter microstructure of the polyimide-I membrane because of the cross-links formed with EDA.

A gas permeation test was conducted to determine the separation performance of the EDA vapor modified polyimide-I membrane in the separation of H₂ and CO₂. The graph of gas permeability and H₂/CO₂ selectivity of the EDA vapor modified polyimide-I membrane against EDA vapor exposure time is shown in FIG. 2c. Referring to FIG. 2c, the permeability of both H₂ and CO₂ across the EDA vapor modified polyimide-I membrane continuously decreased with increasing EDA vapor treatment time because of the decrease in d-space. However, the decrease in CO₂ permeability was faster than that of H₂ permeability because of the smaller kinetic diameter of H₂ gas (2.89 Å) as compared to that of CO₂ gas (3.3 Å), thereby resulting in the significant increase in H₂/CO₂ selectivity from about 1 to about 102 after 10 minutes of EDA vapor exposure. The superior H₂/CO₂ separation performance of the modified polyimide-I membrane was attributed to the reduction in diffusive pathways after EDA vapor modification of the polyimide-I membrane, thereby enabling the modified membrane to become a barrier to CO₂.

Furthermore, to meet the practical requirements of syngas purification, the separation performance of the EDA vapor modified polyimide-I membrane was evaluated by passing an equimolar H₂/CO₂ binary gas system and a pure H₂ or CO₂ gas system across the modified membrane. The results of the gas tests are shown in Table 2 below and FIG. 2d.

TABLE 2

| | | CO₂ | | | |
|---|---|---|---|---|---|
| | | (partial) | H₂ | CO₂ | |
| | | Pressure | permeability | permeability | H₂/CO₂ |
| Sample | Gas | (atm.) | (Barrier) | (Barrier) | selectivity |
| Original | Pure | 3.5 atm | 600 | 581 | 1.03 |
| | Binary | 3.5 atm | 194 | 586 | 0.33 |
| 5 | Pure | 3.5 atm | 73.4 | 1.97 | 37.3 |
| minutes | Binary | 3.5 atm | 29.5 | 3.74 | 7.88 |
| 10 | Pure | 3.5 atm | 32.6 | 0.32 | 102 |
| minutes | Binary | 3.5 atm | 19.4 | 1.17 | 16.6 |

As can be seen in Table 2, the H₂ permeability in the binary gas system of the polyimide-I membrane before and after EDA vapor modification was significantly lower than the H₂ permeability in the pure H₂ gas system. Without being bound by theory, this is believed to be because of the higher condensability of slow moving CO₂ gases dominating the sorption sites on the membrane, hence decimating the transport of fast moving H₂ gas through the membrane. Conversely, the CO₂ permeability in the binary gas system is higher than that in the pure CO₂ gas system. This is attributed to the assisted CO₂ transport by the fast moving H₂ gas. Consequently, the interplay between the fast moving H₂ gas and the slow moving CO₂ gas caused the lower H₂/CO₂ selectivity in the binary gas system as compared to that in pure gas system.

To visualize the separation performance of vapor-phase EDA modified polyimide-I membranes, a trade-off line was plotted for comparison as shown in FIG. 2d which is a guideline to differentiate high performance materials with normal materials. As seen in FIG. 2d, the original membrane in both the pure and binary gas tests fall below the trade-off line. However, the EDA vapor modified polyimide-I membrane in both tests are above the trade-off line and demonstrates superior hydrogen separation performance than that of the original polyimide-I membrane and other conventional polymer membranes based on both pure gas and binary gas tests.

### Example 2

In this Example, Torlon® polyamide-imide flat sheet membranes and a blend of polybenzimidazole (PBI) and Matrimid® 5218 flat sheet membranes were used to confirm the results of Example 1. The Torlon® polyamide-imide membrane has the following structure.

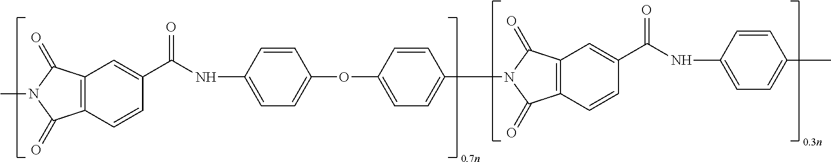

PBI and Matrimid® 5218 have the following structures.

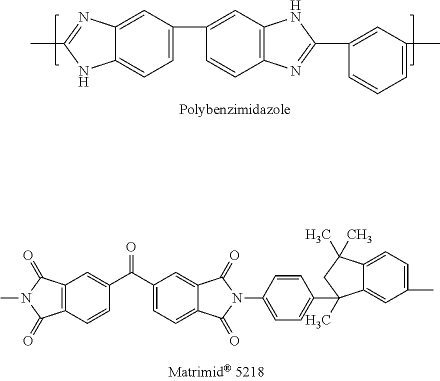

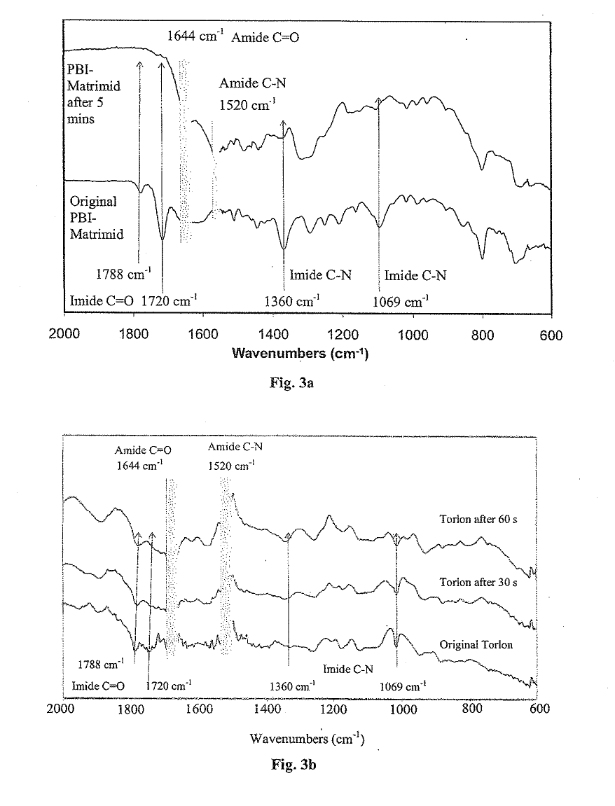

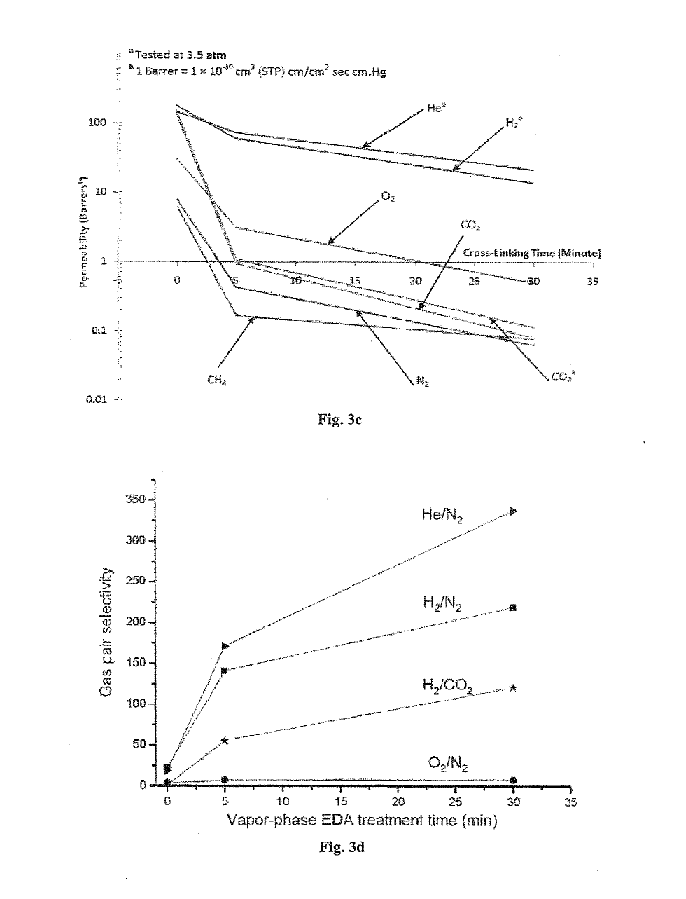

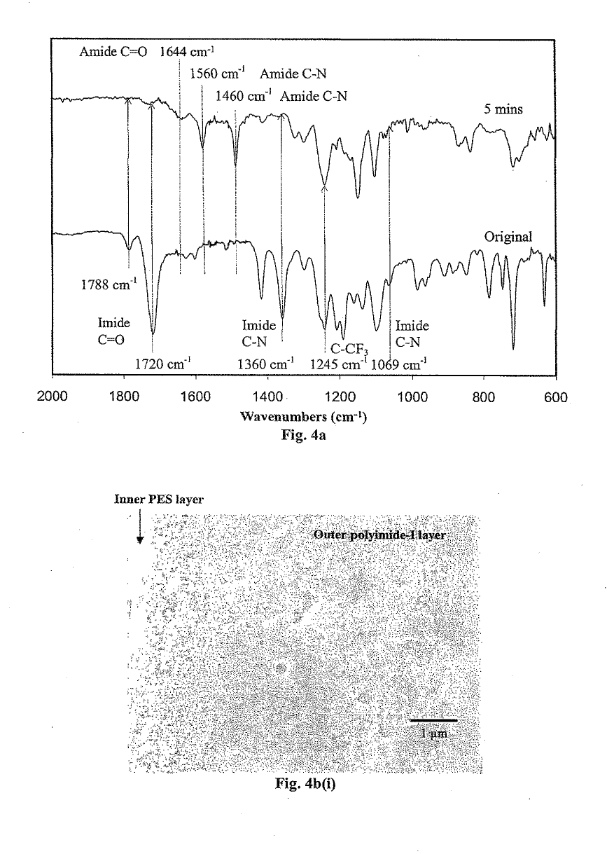

The FTIR-ATR graph of the PBI-Matrimid membrane is shown in FIG. 3a and the FTIR-ATR graph of the Torlon membrane is shown in FIG. 3b. The graphs confirm the FTIR-ATR results of Example 1 because the imide peaks of the original polyimide membrane disappear and are replaced by amide peaks.

The trend of various gas permeabilities across the PBI-Matrimid and the Torlon membranes after vapor-phase EDA modification is shown in FIG. 3c. As seen in FIG. 3c, gas permeability decreased with increasing EDA vapor cross-linking time. The decrease in gas permeability was due to the reduction of diffusive pathways because of the increase in density and rigidity of the cross-linked polyimide-EDA chain structure.

The trend of various gas pair selectivities of the PBI-Matrimid and the Torlon membranes after vapor-phase EDA modifications is shown in FIG. 3d. As seen in FIG. 3d, a comparison of the selectivities showed that the EDA vapor modified PBI-Matrimid and the Torlon membranes has higher He/N₂, H₂/N₂, H₂/CO₂ and O₂/N₂ selectivities than those of the original PBI-Matrimid and the Torlon membranes without modification. This result indicated that the disclosed vapor-phase diamine modification approach not only improves the performance of H₂/CO₂ separation but also the performance of many other gas pair separations.

### Example 3

In this Example, vapor-phase EDA was used to modify a polyimide-I/PES dual layer hollow fiber, a PBI-Matrimid/PSf hollow fiber and a Torlon hollow fiber.

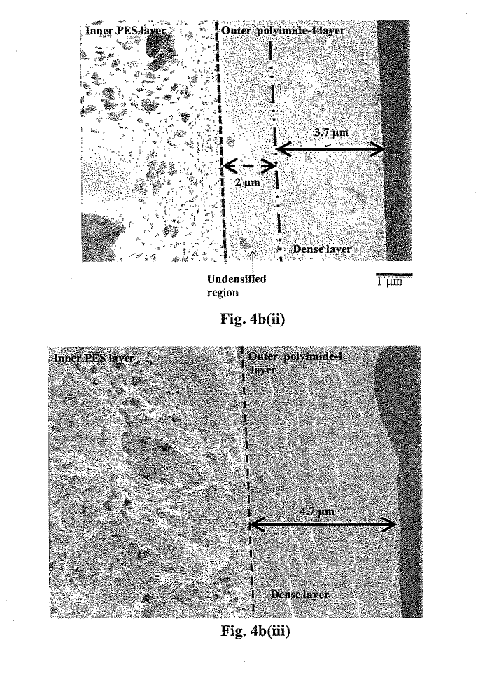

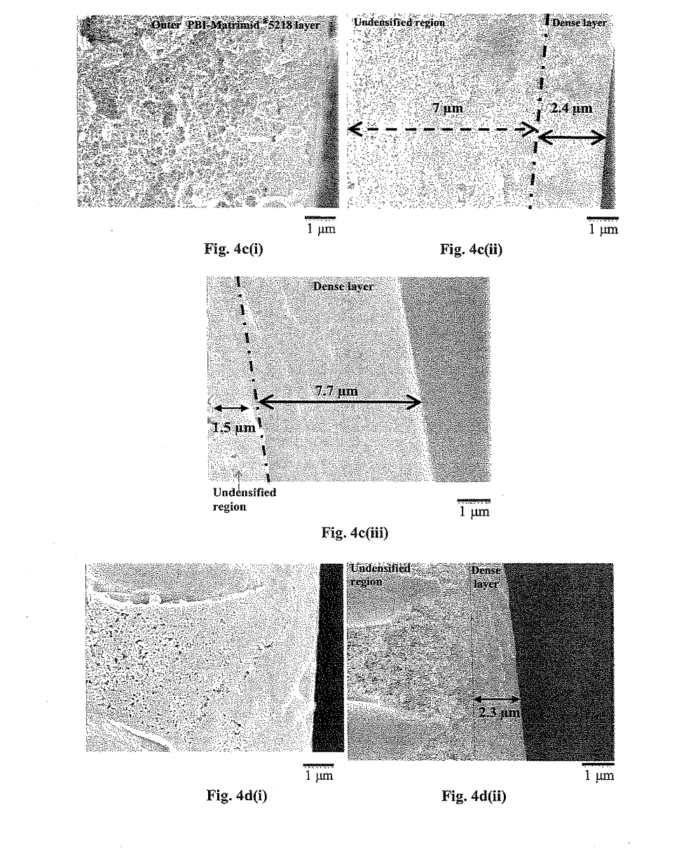

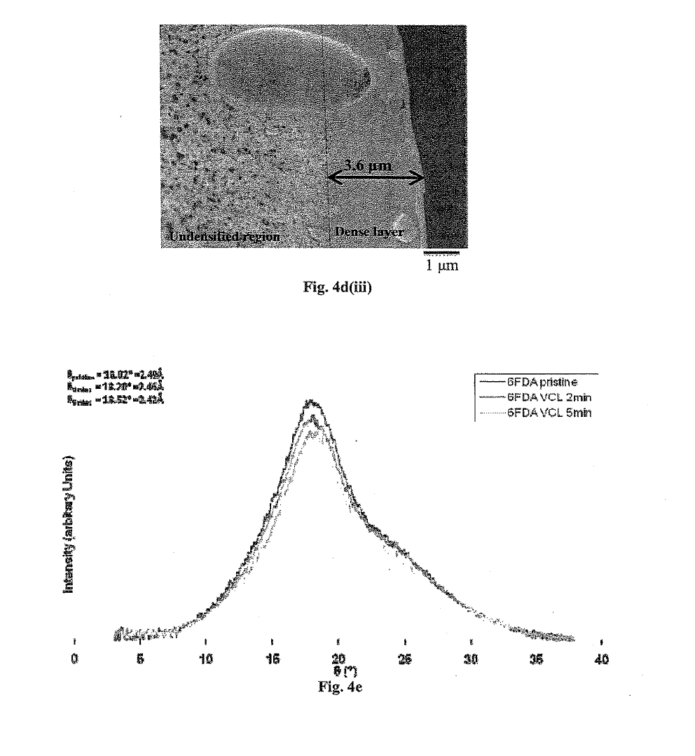

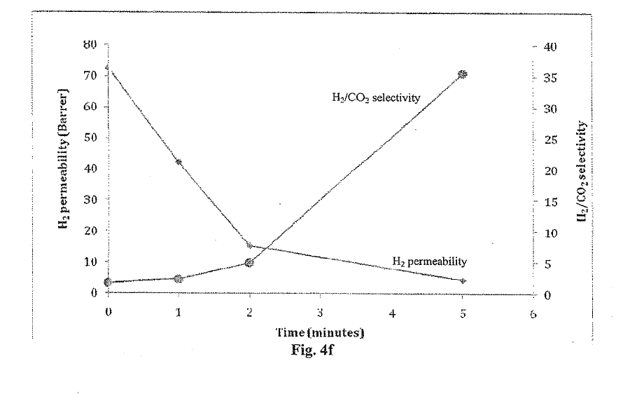

After 5 minutes of exposure to EDA vapor, the polyimide-I hollow fiber membrane was analyzed by FTIR-ATR. FIG. 4a shows the FTIR-ATR graph of the polyimide-I hollow fiber membrane before and after exposure to EDA vapor. As can be seen in FIG. 4a, chemical changes in the polyimide-I hollow fibers were observed after vapor-phase EDA modification. Similar to the flat-sheet polyimide-I membrane of Example 1, the bands at around the asymmetric stretch of the C═O portion of imide groups (1785 cm⁻¹), the symmetric stretch of the C═O portion of imide groups (1718 cm⁻¹) and the stretch of the C—N portion of imide groups (1352 cm⁻¹) from the original polyimide-I hollow fiber membrane disappeared after vapor-phase EDA modification. New polyamide peaks corresponding to band of the C═O portion of amide (CONH) groups and the N—H portion and C—N portion of the CONH groups appeared at around 1644 cm⁻¹ and 1520 cm⁻¹ respectively.

The outermost layer of pristine polyimide-I hollow fibers consisted of sphere-like structures. Upon vapor phase modification, the sphere-like structures on the outermost layer were replaced by a denser layer because of the cross-links formed between the polyimide-I dual layer hollow fiber and EDA. The thickness of this dense layer increased with increasing vapor phase modification time. The FESEM images shown in FIGS. 4b(i) to 4b(iii) prove that there is no dense outermost layer in the original pristine polyimide-I dual layer hollow fiber membrane as seen in FIG. 4b(i). When the polyimide-I dual layer hollow fiber membrane was exposed to EDA vapor for 2 minutes, a 3.7 μm thick dense layer is formed on the outermost layer of the fiber (FIG. 4b(ii)). The thickness of this dense layer is increased to 4.7 μm after 5 minutes of vapor-phase modification (FIG. 4b(iii)). Therefore, in view of the FTIR-ATR graph in FIG. 4a, the FESEM images shown in FIGS. 4b(i) to 4b(iii) explain that the dense layer formed on the outermost surface of the dual layer hollow fiber was attributed to the transformation of polyimide into polyamide.

The FESEM images of the PBI-Matrimid/PSf hollow fibers are shown in FIGS. 4c(i) to 4c(iii) corresponding to 0 min, 2 min and 5 min of vapor phase modification respectively. The FESEM images of the Torlon hollow fibers are shown in FIGS. 4d(i) to 4d(iii) corresponding to 0 seconds, 30 seconds and 60 seconds of vapor phase modification respectively. The results confirm that vapor phase modification forms a dense outer layer on all three samples of hollow fibers.

Table 3 below shows the H₂ and CO₂ permeance and selectivity of the polyimide-I/PES, PBI-Matrimid/PSf, Torlon hollow fibers before and after vapor phase modification. All gases were tested at 35° C. (95° F.) and 20 psi. As can be seen in Table 3, the H₂ and CO₂ permeabilities of all three types of hollow fibers decrease after vapor phase modification and the H₂/CO₂ selectivities increase after modification. These results are consistent with the results seen for the flat sheet polyimide membranes in Examples 1 and 2.

TABLE 3

| | H₂ | CO₂ | Selectivity |
|---|---|---|---|
| Sample Name | (GPU) | (GPU) | (H₂/CO₂) |
| Polyimide-I/PES - original | 72.59 | 42.97 | 1.69 |
| Polyimide-I/PES after 2 min | 15.43 | 4.13 | 3.74 |
| Polyimide-I/PES after 5 min | 4.44 | 0.125 | 35.52 |
| PBI-Matrimid/Psf - original | 27.67 | 6.88 | 4.02 |
| PBI-Matrimid/Psf after 2 min | 21.68 | 3.77 | 5.75 |
| PBI-Matrimid/Psf after 5 min | 13.77 | 1.77 | 7.78 |
| Torlon - original | 7.07 | 1.03 | 6.86 |
| Torlon after 30 secs | 1.32 | 0.12 | 11 |
| Torlon after 1 min | 1.03 | 0.16 | 6.44 |

The XRD graph shown in FIG. 4e indicated that as vapor-phase modification time increased, the d-space between the polymer chains decreased. After 5 minutes of exposure to EDA vapor, the value of θ increased from 18.02° to 18.52°. Using Bragg's Law (nλ=2d sin θ), the value of d, which represents the d-space, decreased from 2.49 Å to 2.42 Å. This confirmed the XRD results in Example 1 and indicated that as the EDA vapor exposure time increased, the microstructure of the polyimide-I dual layer hollow fibers became tighter. This is because the channels available for gas transport became smaller after vapor phase modification. Hence, gas permeability of these modified hollow fibers decreased.

As shown in FIG. 4f, the gas permeability of H₂ decreased from 72.59 Barrer to 4.44 Barrer with increasing vapor-phase modification time. However, H₂/CO₂ selectivity increased from 1.69 to 35.52 with increasing vapor-phase modification time.

For dual layer hollow fibers made from polyimide-I membrane, the maximum duration of vapor phase modification is 5 minutes. After 5 minutes of exposure to EDA vapor, the outermost layer of the polyimide-I membrane will peel off from the fiber. Accordingly, the ideal vapor-phase modification time is between 1-5 minutes.

### Comparative Example

Solution Phase Modification

The polyimide-I flat sheet membrane used in Example was modified by immersing the membrane into a methanol/EDA solution with an EDA concentration of 1.65 mol/L for 5 minutes. After 5 minutes of solution phase modification, the H₂ permeability of the polyimide-I membrane was reduced from 650 Barrer to 100 Barrer and the CO₂ permeability was reduced from 580 Barrer to 22 Barrer. Further, the H₂/CO₂ selectivity increased from a factor of 1 to 4.5.

This is compared with the vapor phase modification of the polyimide-I flat sheet membrane in Example 1. As can be seen from Table 1 above, the H₂ permeability of the polyimide-I membrane from Example 1 reduced from 600 Barrer to 73.4 Barrer and the CO₂ permeability reduced from 581 Barrer to 1.97 Barrer after 5 minutes of EDA vapor exposure. Further, the H₂/CO₂ selectivity increased from a factor of 1.03 to 37.3.

The higher H₂/CO₂ selectivity of 37.3 of vapor phase modified polyimide-I membranes is much higher than the H₂/CO₂ selectivity of 4.5 of solution phase modified polyimide-I membranes. This proves that the vapor modification approach is more effective than the solution modification approach because of the intensive vapor modification on the surface of polyimide membranes.

### APPLICATIONS

Advantageously, the disclosed method provides an improved method to produce membranes that maintain their structural integrity. Advantageously, the vapor-phase modification of polyimide membranes does not result in methanol swelling of the polyimide membrane, which would have been the case if the prior art solution approach of modification is used because the solution approach uses methanol as a solvent for the cross-linking compound.

Additionally, since the vapor-phase modifications are mainly surface modifications, the modifications do not undermine the integrity of the polyimide membrane structure itself and is therefore more suitable for very thin membranes like hollow fiber membranes.

Advantageously, because diamine vapors are used, the diamine solution can be reused, thereby making vapor-phase modification an economical choice when compared to the prior art solution modification approach.

Exemplary separation systems that utilize the disclosed membrane include filtration, gas separation, water treatment, pervaporation, micro-filtration, ultrafiltration, nano-filtration, and reverse osmosis.

Advantageously, the disclosed membrane confers excellent gas selectivity. Accordingly, the disclosed polyimide membrane may be suitable for the separation of fluid mixtures such as a mixture of CO₂ and CH₄ gases, a mixture of H₂ and N₂ gases, a mixture of H₂ and CO₂ gases, a mixture of He and N₂ gases or a mixture of C₂-C₄ hydrocarbons for example.

The polyimide membrane may be used for hydrogen purification in “syngas” production. The polyimide membrane may be used to separate oxygen from air.

The polyimide membrane may also be suitable for separating particles from fluids.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A method for modifying at least one property of a polyimide membrane comprising the step of exposing the polyimide membrane to a surface modification compound in a vapour phase, said surface modification compound having at least one amine group, to thereby modify the at least one property of the polyimide membrane.

2. The method as claimed in claim 1, wherein the surface modification compound is a cross-linking compound having at least two amine groups.

3. The method as claimed in claim 1 or claim 2, comprising the step of, during the exposing step, maintaining the conditions to form an amide bond between imide groups of the polyimide and amine groups of the surface modification compound.

4. The method as claimed in claim 3, wherein the exposing step comprises the steps of maintaining the temperature in the range of 50° F. (10° C.) to 212° F. (100° C.) for 1 minute to 60 minutes.

5. The method as claimed in claim 1 or claim 2, comprising the step of vaporizing a solution of the surface modification compound to generate the vapor phase.

6. The method as claimed in claim 5, comprising the step of agitating the solution of the surface modification compound during the vaporization step.

7. The method as claimed in claim 6, wherein the agitating step comprises passing a gas through the solution of the surface modification compound that is inert to said surface modification compound.

8. The method as claimed in any one of the preceding claims, wherein the surface modification compound comprises an aliphatic hydrocarbon chemically coupled to the amine group.

9. The method as claimed in claim 2, wherein said cross-linking compound comprises two amine groups chemically coupled by a hydrocarbon linker (R), said cross-linking compound being represented by the following formula (Ia):
H₂N—R—NH₂ (Ia)

10. The method as claimed in claim 9, wherein the hydrocarbon linker R is a saturated or unsaturated, branched or straight chain aliphatic hydrocarbon or a saturated or unsaturated aliphatic ring hydrocarbon.

11. The method as claimed in claim 10, wherein the aliphatic group is an alkyl group having 1 to 8 carbon atoms.

12. The method as claimed in claim 1, comprising the step of selecting an aromatic polyimide as the polyimide.

13. The method as claimed in claim 1, wherein the polyimide is represented by the general formula II: 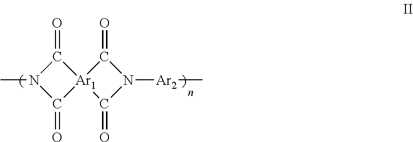
wherein
Ar₁ is a quadrivalent organic group,
Ar₂ is a divalent organic group, and
n is the number of monomer units in the polyimide such that the polyimide has an inherent viscosity of at least 0.3 as measured at 25° C. on a 0.5% by weight solution in N-methylpyrrolidinone.

14. The method as claimed in claim 13, wherein the quadrivalent organic group Ar₁ is selected from the group consisting of: 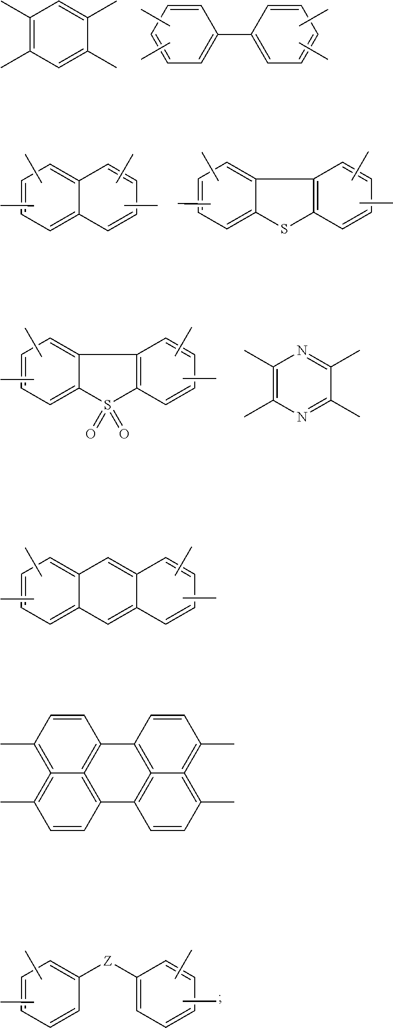
the divalent organic group Ar₂ is selected from the group consisting of: 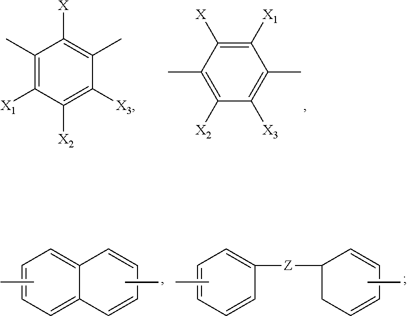
and
Z is selected from the group consisting of: 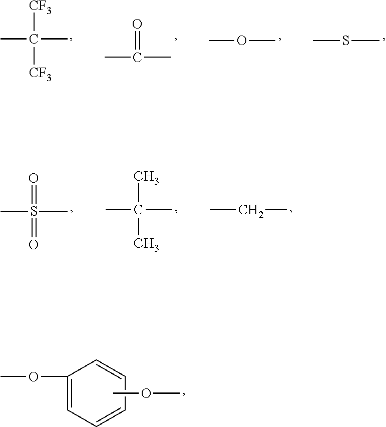
wherein X, X₁, X₂ and X₃ are each independently selected from the group consisting of hydrogen, C₁ to C₅ alkyl group, C₁ to C₅ alkoxy group, phenyl group or phenoxy group.

15. A method of modifying at least one property of a hollow fiber comprising a polyimide membrane, the method comprising the step of exposing the polyimide membrane to a surface modification compound in a vapour phase, said surface modification compound having at least one amine group, to thereby modify the at least one property of the hollow fiber.

16. The method as claimed in claim 15, in which the pore size of the hollow fiber does not substantially change during the exposing step.

17. The method as claimed in claim 16, wherein the exposing step comprises the step of modifying the polyimide membrane that is present in the outer layer of the hollow fiber.

18. The method as claimed in claim 17, wherein the exposing step comprises the steps of maintaining the temperature in the range of 50° F. (10° C.) to 212° F. (100° C.) for 1 minute to 5 minutes.

19. A method for separating at least one fluid or particle from a mixture comprising the steps of:
(a) contacting the mixture with one side of a membrane made in the method of claim 1; and
(b) applying a pressure to the one side of the membrane to cause the at least one fluid or particle to permeate said membrane.

20. A method for separating carbon dioxide from a gas mixture comprising carbon dioxide and at least one of methane and hydrogen, the method comprising the steps of:
(a) contacting the gas mixture with one side of a membrane made in the method of claim 1; and
(b) applying a pressure to the gas mixture in contact with said treated polyimide membrane to cause at least a portion of said carbon dioxide present in said gas mixture to permeate said treated polyimide membrane.
